(19) United States
(12) Patent Application Publication
(10) Pub. No.: US 2018/0358529 A1
(43) Pub. Date: Dec. 13, 2018

(54) Thermoelectric Module

(71) Applicant: Deutsches Zentrum für Luft- und Raumfahrt e.V., Koeln (DE)

(72) Inventors: Reinhard Sottong, Sinzig (DE); Martin Schmücker, Essen (DE)

(21) Appl. No.: 15/780,841

(22) PCT Filed: Dec. 2, 2016
(86) PCT No.: PCT/EP2016/079573

§ 371 Date: Jun. 1, 2018

(30) Foreign Application Priority Data
Dec. 2, 2015 (DE) 10 2015 224 020.7

(51) Int. Cl. H01L 35/06; H01L 35/20; H01L 35/30; H01L 35/32

(52) U.S. Cl. CPC H01L 35/06; H01L 35/32; H01L 35/30; H01L 35/20

(57) ABSTRACT

The invention relates to a thermoelectric module with a thermoelectric element for converting a temperature gradient between the two ends of the thermoelectric element into an electric voltage, an electrically conductive heat conducting element which is arranged between the thermoelectric element and a warm medium in order to thermally couple the high-temperature side of the thermoelectric element to the warm medium, and/or an electrically conductive heating element which is arranged between the thermoelectric element and a cold medium in order to thermally couple the low-temperature side of the thermoelectric element to the cold medium. The invention is characterized in that the electrically conductive heat conducting element is designed as a spring element which is elastic parallel to the direction of progression of the temperature gradient t.

The invention relates to a thermoelectric module.

Thermoelectric modules are used for converting a temperature gradient between the two ends of the thermoelectric element into an electric voltage.

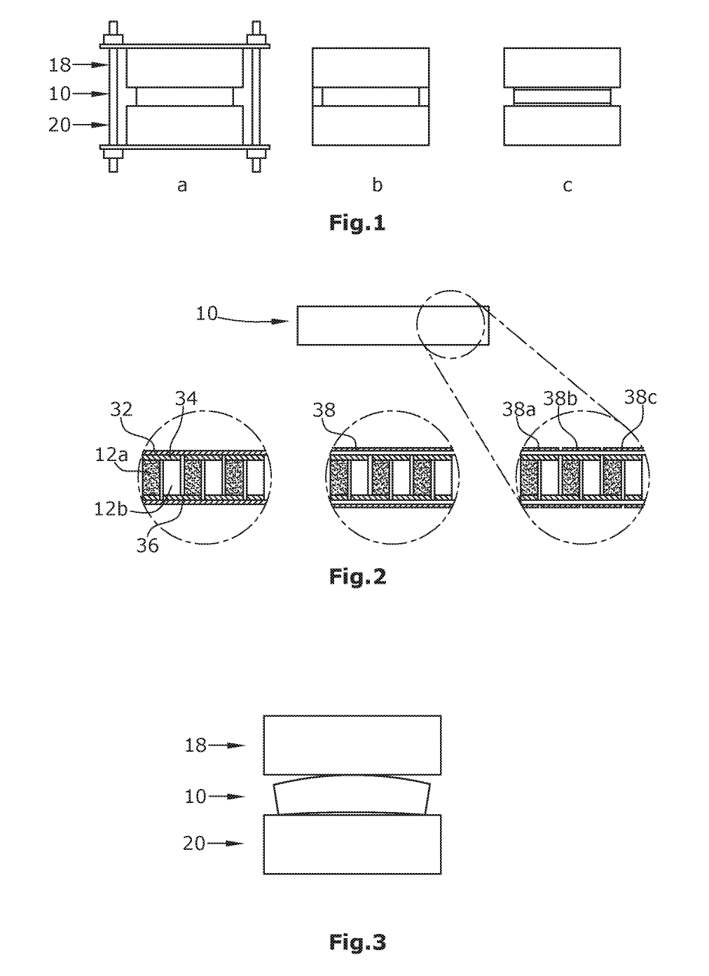

According to the state of the art, thermoelectric modules are in most cases produced in planar geometry, wherein the elements of which a thermoelectric module consists are connected to each other by force locking or by material bonding. The general configuration of a thermoelectric module is illustrated in FIG. 1 in three different variants. All variants have in common that the thermoelectric module 10 is arranged between a hot side 18 and a cold side 20. In the variant according to FIG. 1a, for achieving a better contacting, an external application of force is performed by way of a screw connection. In FIG. 1b, a force-locking connection is effected by a closed configuration while, in FIG. 1c, there is shown a design with material bonding throughout.

The exact configuration of a thermoelectric module 10 as known from the state of the art is shown in FIG. 2. The individual thermoelectric elements 12a, 12b are electrically connected to each other via metal plates 34, 36. These at the same time serve for thermal conductance so that the heat of the hot medium can be supplied e.g. to the thermoelectric element 12a, 12b. The module comprises an insulating ceramic support plate 32 which electrically decouples the metallic bridge elements. Said support plate is further effective to reduce environmental influences which may act on the thermoelectric module. According to FIG. 2b, the outer side of the ceramic plate 32 can additionally have a metal plate 38 mounted to it. It is also possible to apply a ceramic insulating layer as a layer on the metal. Alternatively, instead of said continuous metal plate 38, the outer side of the ceramic plate 32 can also have metallic bridges 38a, 38b, 38c arranged on it (see FIG. 2c).

A disadvantage of the above mentioned design resides in that the different materials have different thermal expansion coefficients so that, when the thermoelectric module 10 is heated, it will undergo deformation because the hot side of the thermoelectric element will expand more than its cold side (see FIG. 3). The deflection of the thermoelectric element will lead to a deterioration of the thermal coupling between the heat source and the heat sink. Further, this deformation and the different degrees of expansion of different materials have the effect that, at contact sites between the latter (particularly at the transition from the metallic bride to the thermoelectric material), high thermomechanical tension is induced that may cause detachment or fissures at these sites and thus will destroy the module.

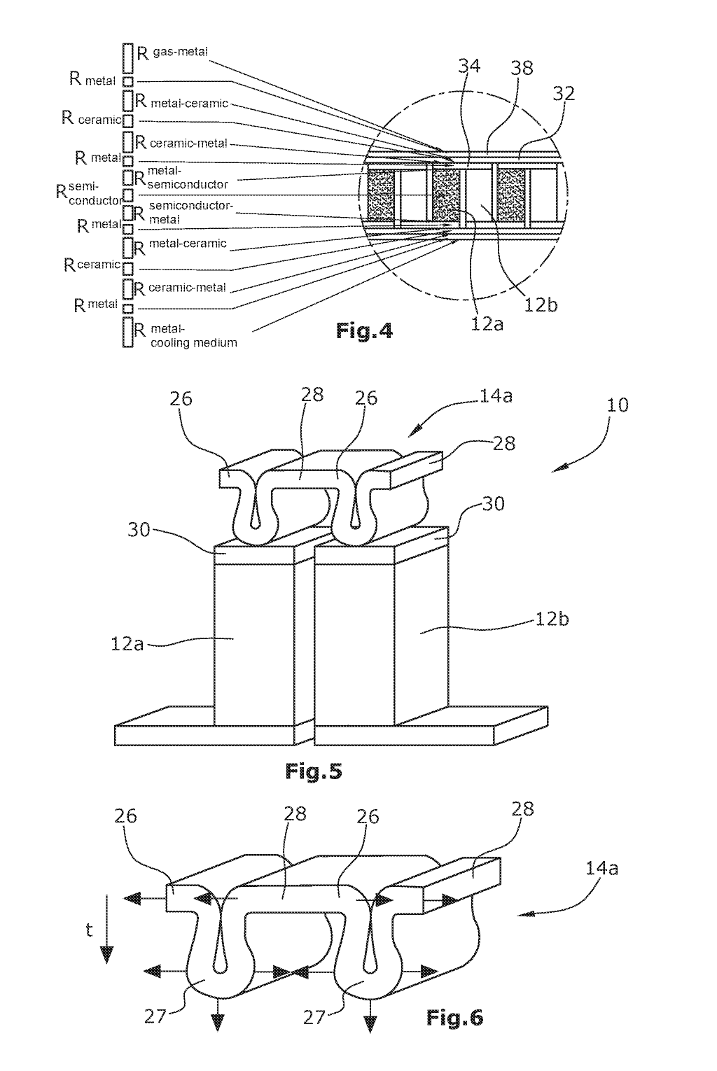

Further, due to the large number of the materials used, numerous thermal resistances are caused which are of consequence particularly because thermal resistances between different materials (e.g. ceramic and metal) will turn out to be particularly high. In FIG. 4, these thermal resistances are represented in detail. The first among them is caused by the heat transmission between the hot medium, e.g. a gas, and the outer metal plate 38. The next one is generated at the transition between the metal plate 38 and the ceramic plate 32. The next one is generated at the transition between the ceramic plate 32 and the metal bridge 34. The next one is generated at the transition between the metal bridge 34 and the thermoelectric elements 12a, 12b. In a similar manner, further thermal resistances occur in the direction of the heat sink.

High thermal resistances will lead to a lower temperature gradient between the two ends of the thermoelectric elements 12a, 12b, will cause a reduced yield of voltage.

Information on the state of the art, particularly on flexible thermoelectric elements, can be gathered from the following publications:

WO2015050077-A1; Fuji Film Corp, Maruyama Yoichi, Hayashi Naoyuki, 9 Apr. 2015

WO2014001337-A1; DE102012105743-A1, ElringKlinger A G, Beyerlein G., 3 Jan. 2014

DE102012105086-A1; WO2013185903-A1; DE102012105086-B4; Karlsruher Inst Technologie, Gall A; Gueltig M; Kettlitz S; Lemmer U, 19 Dec. 2013

CN202888246-U; Jiangsu Internet Things Res Dev Cent, Wang R; Cao E; Chen L; Wu Q, 17 Apr. 2013

CN202855804-U; Jiangsu Internet Things Res Dev Cent, Wu Q, Chen L; Cao E; Wang R; 3 Apr. 2013

CN202855806-U; Jiangsu Internet Things Res Dev Cent, Chen L; Wu Q, Cao E; 3 Apr. 2013

CN102931337-A; Jiangsu Internet Things Res Dev Cent, Cao E; Wang R; Chen L; Wu Q, 13 Feb. 2013

DE102010031829-A1; Novaled A G, Blochwitz-Nimoth J; Werner A, 3 Feb. 2011 US 20110016888 A1, WO2011009935-A1; CA2768902-A1; EP2457270-A1; EP2457270-B1 BASF Se, Frank Haass, Madalina Andreea Stefan, Georg Degen, 27 Jan. 2011

CN101894905-A; CN101894905-B, Jiangxi Namike Thermoelectricity Electronics Co Ltd, Zheng J., 24 Nov. 2010

SU1175312-A; Bovin A V; Kirsanov V S; Pustovalov A A; 30 Nov. 1990

Information on the thermomechanical tensions which are generated in thermoelectric modules can be gathered from the following publications:

Klein Altstedde, M.; Sottong, R.; Freitag, O.; Kober, M.; Dreißigacker, V.; Zabrocki, K.; Szabo, P., J. electron. mater. 44, 6 (2015) 1716-1723; doi:10.1007/s11664-014-3523-5

J. Sharp, J. Bierschenk, J. electron. mater. 44, 6 (2015) 1763-1767, doi: 10.1007/s11664-014-3544-0

T. Ochi et al., J. electron. mater. 43, 6 (2014) 2344-2347 doi: 10.1007/s11664-014-3060-2

S. Turenne, Th. Clin, D. Vasilevskiy, R. A. Masut, J. electron. mater. 39, 9 (2010) 1926-1933 doi: 10.1007/s11664-009-1049-z

E. Suhir, A. Shakouri, J. appl. mech. 80, 2 (2013) 021012 doi: 10.1115/1.4007524

T. Sakamoto, T. Iida et al., J. electron. mater. 43, 6 (2014) 1620-1629 doi: 10.1007/s11664-013-2814-6

It is an object of the invention to provide a thermoelectric module having a higher efficiency and a longer operating life.

According to the invention, the above object is achieved by the features defined in claim 1.

The thermoelectric module according to the invention comprises a thermoelectric element for converting the temperature gradient between the two ends of the thermoelectric element into an electric voltage. Preferably, the thermoelectric module comprises a plurality of such thermoelectric elements which are arranged adjacent to each other in the thermoelectric module.

The thermoelectric module further comprises an electrically conductive heat conducting element which is arranged between the thermoelectric element and a warm medium in order to thermally couple the high-temperature side of the thermoelectric element to the warm medium. Alternatively or additionally, the thermoelectric module comprises an electrically conductive heat conducting element which is arranged between the thermoelectric element and a cold medium in order to thermally couple the low-temperature side of the thermoelectric element to the cold medium.

Thus, the electrically conductive heat conducting element is arranged between the thermoelectric element and the heat source and respectively the heat sink.

According to the invention, the electrically conductive heat conducting element is designed as a spring element which is elastic parallel to the direction of progression of the temperature gradient.

Thereby, it is rendered possible to compensate for tolerances of component parts so that the component parts of the thermoelectric module do not need to be produced anymore all too precisely. By the electrically conductive heat conducting element, an electric contacting takes place on at least one end of the thermoelectric element so that the voltage generated by the latter can be dissipated.

In the state of the art, the electric contacting of the thermoelectric elements has heretofore been performed via metal bridges arranged on the inner side of the ceramic plate in the direction of the thermoelectric element. Thus, the heat conduction from the heat source to the thermoelectric elements was effected via the ceramic plate and only subsequently via the metal bridges. As a consequence, such thermoelectric modules of the state of the art had a higher thermal resistance. In contrast thereto, the invention makes it possible to establish a direct thermal coupling between the heat source and the thermoelectric element via the electrically conductive heat conducting element so that the thermal resistance can be reduced. Thereby, the temperature gradient between the two ends of the thermoelectric element can be increased, thus achieving a higher voltage yield.

It is preferred that the electrically conductive heat conducting element comprises a metal or a metal alloy. Thereby, a particularly good heat conductance from the heat source and respectively the heat sink to the respective side of the thermoelectric element can be guaranteed.

According to a preferred embodiment, the thermoelectric module comprises an electrically insulating, planar, fiber-ceramic support element for supporting the electrically conductive heat conducting element. Particularly, said support element extends vertically to the direction of the temperature gradient. The fiber-ceramic support element comprises at least one recess having the electrically conductive heat conducting element passing through it, so that an outer portion of the heat conducting element is arranged outside the fiber-ceramic support element and an inner portion of the heat conducting element is arranged inside the fiber-ceramic support element. By such a support element of fiber-composite ceramic material, the electrically conductive heat conducting elements are electrically insulated from each other. In comparison to monolithic ceramic plates used up to now, a composite ceramic material has a higher resistivity against mechanical and thermomechanical load peaks, resulting in an increased operating life of the thermoelectric module. Further, due to its composite ceramic material, the thermoelectric module, can be designed in any desired module geometries deviating from a planar shape.

According to a preferred embodiment, the electrically conductive heat conducting element has a loop-shaped design, wherein the loop comprises a first and a second open end, said ends respectively extending parallel to the fiber-ceramic support element outside thereof and forming a contact surface to the warm and respectively cold medium. These two open ends of the loop are preferably adapted to be moved toward each other and away from each other, so that mechanical stresses parallel to the module surface that are generated due to thermal expansion can be compensated via the shape of the loop-shaped heat conducting element without mechanical stresses occurring at the contact surface to the thermoelectric element. The reason for this is that an expansion of the heat conducting element parallel to the surface of the thermoelectric module (i.e. vertically relative to the direction of the temperature gradient) has an effect at least primarily on the first and the second open end of the loop and thus has no effect on that portion of the heat conducting element that is in contact with the thermoelectric element. This is the round central element of the loop that is connected to the thermoelectric element by material bonding and/or by a force-locking connection. By this part of the loop-shaped portion of the heat element, it is possible to compensate particularly for height differences parallel to the direction of the temperature gradient because the heat conducting element has elastic properties in this direction.

According to a preferred embodiment, it is provided that, between the heat conducting element and the thermoelectric element, a heat distribution plate is arranged for homogenous heat distribution at the first and respectively second end of the thermoelectric element. Said heat distribution plate preferably comprises a metal or a metal alloy. It is preferred that, between the heat conducting element and the thermoelectric element, there is arranged exclusively a heat distribution plate so that no further components are provided there. Thereby, it is rendered possible to achieve a reduction of the thermal resistance between the heat source and respectively the heat sink and the thermoelectric element because, for instance, the heat will be transferred from the heat source to the heat conducting element, will be conducted from there to the heat distribution plate and from the latter will be directly pass into the thermoelectric element. Since the heat conducting element and the heat distribution plate can e.g. both be made of metal, the thermal resistance between these two components is relatively low. Particularly, according to the invention, it is not necessary to provide a heat transition between a ceramic component and a metal component, which would result in an increased thermal resistance. The reason therefor is that, in the thermoelectric module of the invention, ceramic components do not participate in heat conduction.

It is preferred that the thermoelectric element has a planar or also a curved shape. The selection of the shape is rendered possible by producing the support element from fiber-composite ceramic material.

Further, it is preferred that the heat conducting element forms a bridge between two adjacent thermoelectric elements wherein, for this purpose, a heat conducting element particularly comprises two loops, a first one of them serving for contacting the first thermoelectric element and the second one serving for contacting the second thermoelectric element.

Opposite to the respective adjacent heat conducting element which again can consist of two loops, an insulation can be effected by the fiber-ceramic support element.

It is preferred that the thermal expansion coefficient of the heat distribution plate is substantially identical with the thermal expansion coefficient of the thermoelectric element. Thereby, it can be achieved that, in case of an expansion of the heat distribution plate due to the temperature increase, no large stresses will occur at the thermoelectric element. Because of the flexible design of the heat conducting element whose contact face to the thermoelectric element is movable within a specific range, particularly also in a direction parallel to the module surface, relative movements between the heat conducting element and the heat distribution plate can be compensated in a direction parallel to the module surface. Alternatively, the heat conducting element and the heat distribution plate can also be connected to each other by material bonding. In this case, the spring function will take over a reduction of the occurring thermomechanical stresses.

It is preferred that a direct metallic connection exists between the thermoelectric element and the hot and respectively cold medium. This makes it possible to achieve an improved thermal coupling in comparison to the state of the art.

Further, it is preferred that the size and the shape of the recesses of the fiber-ceramic support element are adapted to the size and the shape of the heat conducting element so that the fiber-ceramic element is in direct abutment on the outer edge of the heat conducting element and insulates the thermoelectric element from the hot and respectively cold medium. Thereby, the efficiency of the thermoelectric module can be further increased.

It is preferred that all of the described components are provided in a multiple number in the thermoelectric module so that the thermoelectric module comprises a plurality of thermoelectric elements which are electrically connected to each other via the electrically conductive heat conducting elements. The plurality of heat conducting elements are held by the fiber-ceramic support element which thus lends stability to the thermoelectric module.

Hereunder, preferred embodiments of the invention will be explained with reference to the Figures.

The following is shown:

FIGS. 1 and 2 show the configuration of thermoelectric modules according to the state of the art,

FIG. 3 shows the deformation of a thermoelectric module according to the state of the art,

FIG. 4 shows the thermal resistances in a thermoelectric module according to the state of the art,

FIG. 5 shows a first embodiment of the thermoelectric module according to the invention,

FIG. 6 is an isolated view of a heat conducting element according to the invention,

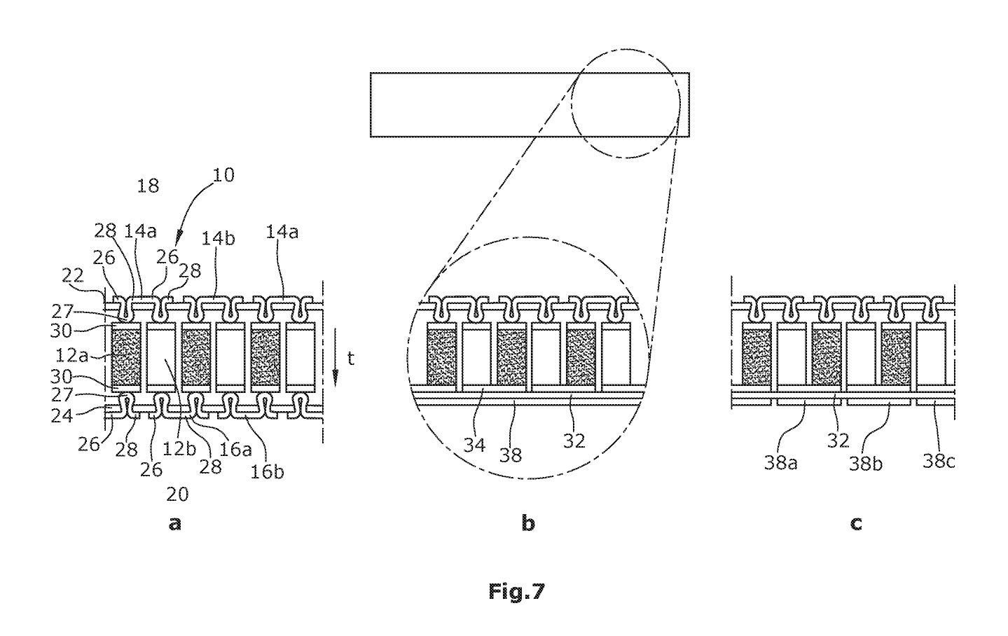

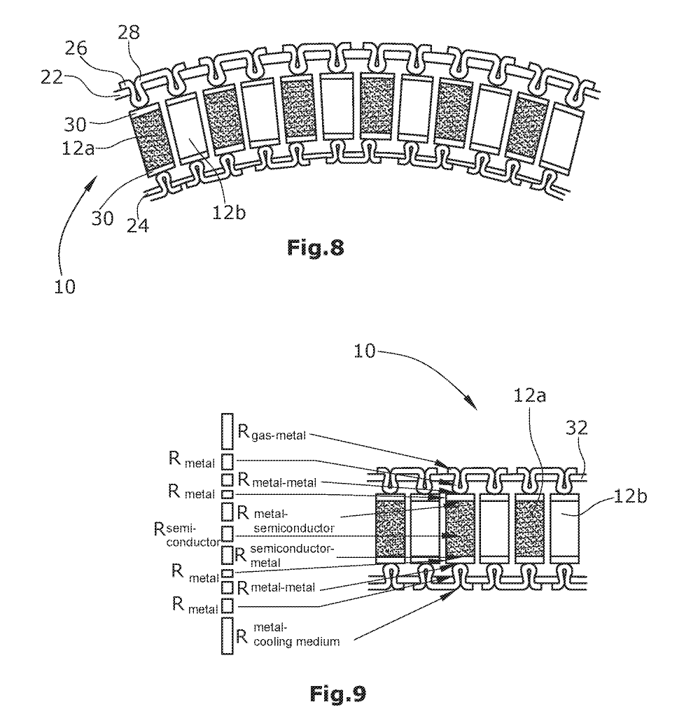

FIGS. 7 and 8 show further embodiments of an thermoelectric element according to the invention,

FIG. 9 shows the thermal resistances in an embodiment of the thermoelectric element according to the invention.

FIGS. 1 and 2 have already been explained in connection with the state of the art.

FIG. 3 illustrates the manner in which a thermoelectric module 10 known from the state of the art is expanding on its hot side 18 more than on its cold side 20. This leads to deformation of the module, to a deterioration of the thermal coupling of the individual components and thus to a reduction of the achievable electric power of the thermoelectric module 10.

This effect is further intensified since, in thermoelectric modules known from the state of the art, a plurality of different materials are used, with high thermal resistances existing between them (see FIG. 4). This holds true particularly because the heat transition between different materials, e.g. between metal and ceramic, is subject to a high thermal resistance.

According to the invention, however, the fiber-ceramic support element 22, 24 is not used as a heat conductor but only for electric insulation of the heat conducting elements 14a, 14b, 16a, 16b as well as for mechanical stabilization of the thermoelectric module (see FIGS. 7 and 9, among others). Particularly from FIG. 9, it is evident that the thermoelectric module 10 of the invention makes it possible to reduce the thermal resistances between the heat source and respectively the heat sink and the thermoelectric module 10. This holds true both for the number of thermal resistances and for their type since, for instance, a heat transition between a ceramic material and metal is entirely avoided and ceramic materials with high thermal resistance do not participate in the heat conduction. Thereby, a higher heat flow and thus a more efficient use of the existing heat quantity are rendered possible.

An exemplary design of the thermoelectric module 10 of the invention is shown in FIG. 5. On the top side of each thermoelectric element 12a, 12b, there is arranged a respective heat distribution plate 30 of metal, whose thermal expansion coefficient preferably is identical with that of the thermoelectric element 12a, 12b so that non thermoelectric tension will occur at the transition between these two elements. Thermally and electrically coupled to the top side of the heat distribution plates is the electrically conductive heat conducting element 14a. The latter comprises two loops, a first one of them serving for contacting the left-hand heat distribution plate 30 and the second one serving for contacting the right-hand heat distribution plate 30. This contacting is effected respectively by the round central element of the loop, wherein, additionally, the respective first and second open end 26, 28 of each loop is thermally coupled to the heat source, not shown.

FIG. 6 illustrates in which manner the heat conducting element 14a can become elastically deformed: On the one hand, an elastic deformation is possible in a direction parallel to the module surface, i.e. vertically to the direction of the temperature gradient t. Into this direction the heat conducting element 14a can expand without subjecting the thermoelectric elements 12a, 12b or the heat distribution plates 30 to substantial mechanical stresses. This is because also the round central portion 27 of each loop is movable independently from the two open ends 26, 28 of the loop in parallel to the surface of the module so that possible movements on the open ends 26, 28 can be compensated.

Additionally, the heat conducting element that is designed as a spring element has resilient properties in the direction of the temperature gradient t so that, in this manner, e.g. height differences in the thermoelectric elements 12a, 12b can be compensated.

The loop-shaped heat conducting elements 14a, 14b, 16a, 16b of the invention can be used in different manners: According to FIG. 7a, they are used both on the top side and on the bottom side of the thermoelectric elements 12a, 12b while in each case being held by a fiber-ceramic support plate 22, 24, the latter comprising recesses having the loops of the heat conducting element passing through them. The fiber-ceramic support plate 22, 24 further provide for a thermal insulation of the space between the thermoelectric elements 12a, 12b against the heat source and the heat sink.

By way of alternative, it is possible that one side of the thermoelectric element 10 is formed e.g. as the cold side according to the state of the art by using, for the electric contacting of the thermoelectric elements 12a, 12b, metal bridges 34 that are supported by the ceramic plate 32 which itself is connected to an outer metal plate (see FIG. 7b). This design of the cold side of the thermoelectric element 10 corresponds to the design from the state of the art according to FIG. 1b.

Further, according to FIG. 7c, one side of the thermoelectric element, e.g. the cold side, can comprise, on the outer side of the ceramic plate 32, individual metal plates 38a, 38b (DBD, DCB substrates with optionally adapted metallization).

According to FIG. 8, the thermoelectric module 10 can also have a curved shape. This is rendered possible by the use of the fiber-ceramic support element.

In all embodiments of the thermoelectric module, it is possible that the thermoelectric elements 12a, 12b are connected to each other at a respective displacement via an electrically conductive heat conducting element 14a, 14b, 16a, 16b. As can be seen in FIG. 7a, the two left-hand thermoelectric elements 12a, 12b are connected to each other via the heat conducting element 14a while the second and the third thermoelectric element 12b, 12a are connected to each other via the lower heat conducting element 16a. The third and the fourth thermoelectric element 12a, 12b are again connected via the upper heat conducting element 14b, etc. Thereby, a serial connection of a plurality of thermoelectric elements can be achieved, as is known from the state of the art.

1. A thermoelectric module comprising:
a thermoelectric element for converting a temperature gradient between the two ends of the thermoelectric element into an electric voltage,
an electrically conductive heat conducting element which is arranged between the thermoelectric element and a warm medium order to thermally couple the high-temperature side of the thermoelectric element to the warm medium,
wherein
the electrically conductive heat conducting element is designed as a spring element which is elastic parallel to the direction of progression of the temperature gradient t.

2. The thermoelectric module according to claim 1, wherein the electrically conductive heat conducting element comprises a metal or a metal alloy.

3. The thermoelectric module according to claim 1, further comprising an electrically insulating, planar, fiber-ceramic support element for supporting the electrically conductive heat conducting element,
wherein fiber-ceramic support element particularly extends vertically to the direction of the temperature gradient,
wherein the fiber-ceramic support element comprises at least one recess having the electrically conductive heat conducting element passing through it,
so that an outer portion of the electrically conductive heat conducting element is arranged outside the fiber-ceramic support element and an inner portion of the electrically conductive heat conducting element is arranged inside the fiber-ceramic support element.

4. The thermoelectric module according to claim 1, wherein the electrically conductive heat conducting element has a loop-shaped design, wherein the loop comprises a first and a second open end, said ends respectively extending parallel to the fiber-ceramic support element outside thereof and forming a contact surface to the warm and respectively cold medium, and the round central element of the loop is connected to the thermoelectric element by force locking or by material bonding.

5. The thermoelectric module according to claim 1, wherein, between the electrically conductive heat conducting element and the thermoelectric element, particularly exclusively, a heat distribution plate is arranged for homogenous heat distribution at the first and respectively second end of the thermoelectric element, said heat distribution plate comprising preferably a metal or a metal alloy.

6. The thermoelectric module according to claim 1, wherein the thermoelectric module has a planar or curved shape.

7. The thermoelectric module according to claim 1, wherein the electrically conductive heat conducting element forms a bridge between two adjacent thermoelectric elements wherein, for this purpose, the electrically conductive heat conducting element particularly comprises two loops, a first one of them serving for contacting the first thermoelectric element and the second one serving for contacting the second thermoelectric element.

8. The thermoelectric module according to claim 5, wherein the thermal expansion coefficient of the heat distribution plate is identical with the thermal expansion coefficient of the adjacent thermoelectric element.

9. The thermoelectric module according to claim 1, wherein a direct metallic connection exists between the thermoelectric element and the hot and respectively cold medium.

10. The thermoelectric module according to claim 3, wherein the size and the shape of the recess of the fiber-ceramic support element are adapted to the size and the shape of the electrically conductive heat conducting element so that the fiber-ceramic support element is in direct abutment on the outer edge of the electrically conductive heat conducting element and insulates the thermoelectric element from the hot and respectively cold medium.

11. A thermoelectric module comprising:
a thermoelectric element for converting a temperature gradient between the two ends of the thermoelectric element into an electric voltage,
an electrically conductive heat conducting element which is arranged between the thermoelectric element and a cold medium in order to thermally couple the low-temperature side of the thermoelectric element to the cold medium,
wherein
the electrically conductive heat conducting element is designed as a spring element which is elastic parallel to the direction of progression of the temperature gradient t.
